(19) United States
(12) Patent Application Publication
(10) Pub. No.: US 2017/0294909 A1
(43) Pub. Date: Oct. 12, 2017

(54) Power-Up Based Integrated Circuit Configuration

(71) Applicant: Microchip Technology Incorporated, Chandler, AZ (US)

(72) Inventors: James Bartling, Chandler, AZ (US); Bryan Kris, Gilbert, AZ (US)

(73) Assignee: Microchip Technology Incorporated, Chandler, AZ (US)

(21) Appl. No.: 15/485,065

(22) Filed: Apr. 11, 2017

Related U.S. Application Data
(60) Provisional application No. 62/321,699, filed on Apr. 12, 2016.

(51) Int. Cl. H03K 17/22; G11C 5/14

(52) U.S. Cl. CPC H03K 17/22; G11C 5/148

(57) ABSTRACT

An integrated circuit having a plurality of selectable modes, functions and/or characteristics may be configured at the time of product manufacture by providing an appropriate resistance value pull-up resistor at an external connection (pin) of the integrated circuit package. At least one external connection (pin) may be used for such configuration of the integrated circuit. This is done without having to program the integrated circuit before placing on the product printed circuit board. The same integrated circuit may thus be used for a plurality of different products without requiring any pre-programming thereof. The integrated circuit's personality (desired characteristics) will be programmed automatically as soon as power is first applied to the finished product printed circuit board. Once the integrated circuit has been configured at power up, the external at least one connection (pin), initially used for configuration, can be used for either analog or digital input, output or input/output.

### RELATED PATENT APPLICATION

This application claims priority to commonly owned U.S. Provisional Patent Application No. 62/321,699; filed Apr. 12, 2016; which is hereby incorporated by reference herein for all purposes.

### TECHNICAL FIELD

The present disclosure relates to integrated circuit devices, and, in particular, to a power-up based configuration of such a device.

### BACKGROUND

In today's technology, integrated circuit configuration is accomplished through Metal (permanent), Bond (permanent after packaging), or configuration fuses (flexible but not available until after flash is functional). There are some functions such as Vreg surge current limits that should be flexible but not available before flash is available. The Metal Option: fixed during fabrication with no flexibility. Requires multiple masks and multiple parts in inventory. The Bond option: fixed at time of packaging with limited flexibility and requires multiple parts in inventory. The Configuration Fuses: Only one part in inventory. Flexible—part can be reconfigured for different applications. Limitation—part can only be configured after fuses are available but not during a power-up sequence before the fuses are ready. This creates another issue of start-up time versus surge current: a fast start up time, e.g., critical control applications may require large surge currents and therefore needs a robust power supply. However, many applications cannot tolerate large surge currents, e.g., solar cell, battery power supplies, and energy harvesting. Therefore, configuration fuses are unacceptable to use when an integrated circuit is powering up before configuration fuse selection can be made.

### SUMMARY

Hence, there is a need for a flexible way to configure an integrated circuit during a power-up sequence.

According to an embodiment, an integrated circuit device may comprise: a plurality of external connections; and a pull-down resistor internal to the integrated circuit device and coupled between a one of the external connections and a power supply common; wherein the integrated circuit device may be configured during power-up to a first or a second operating mode depending upon whether an external pull-up resistor may or may not be coupled between a power supply voltage and the one of the external connections.

According to a further embodiment, a switch may be coupled between the pull-down resistor and the power supply common, wherein the switch may be closed during the power-up and open after the power-up. According to a further embodiment, the switch may be a field effect transistor.

According to a further embodiment, a first logic level may be detected and stored in the integrated circuit device when the external pull-up resistor may not be coupled to the one of the external connections; and a second logic level may be detected and stored in the integrated circuit device when the external pull-up resistor may be coupled to the one of the external connections, wherein the stored first or second logic level may be used to determine the configuration of the integrated circuit device to the first or second operating mode, respectively.

According to a further embodiment, the first or the second logic level may be stored in a memory device of the integrated circuit device. According to a further embodiment, the memory device may be a D-flipflop whose input may be coupled with the one of the external connections through a buffer. According to a further embodiment, the first logic level may be a logic 0 and the second logic level may be a logic 1. According to a further embodiment, the first operating mode may be a default mode and the second operating mode may be an alternate mode. According to a further embodiment, the first and second operating modes select appropriate functions and/or characteristics of the integrated circuit device. According to a further embodiment, the integrated circuit device may be a microcontroller.

According to a further embodiment, a tri-state or open drain driver may be internal to the integrated circuit device and coupled to the one of the external connections. According to a further embodiment, the first or second logic level may be stored in the memory device of the integrated circuit device during assertion of a power-on-reset (POR). According to a further embodiment, the first or second logic level may be stored in the memory device of the integrated circuit device during assertion of a voltage regulator not enabled.

According to a further embodiment, may comprise: a plurality of pull-down resistors internal to the integrated circuit device and coupled between at least some of the external connections and a power supply common; wherein the integrated circuit device may be configured during power-up to at least one first and/or at least one second operating mode depending upon whether an external pull-up resistor may or may not be coupled between a power supply voltage and the at least some of the external connections.

According to another embodiment, a method for selecting an operating mode for an integrated circuit device may comprise the steps of: providing a plurality of external connections on the integrated circuit device; providing a pull-down resistor internal to the integrated circuit device and coupled between a one of the external connections and a power supply common; providing an external pull-up resistor; wherein when the external pull-up resistor may be not coupled between a power supply voltage and the one of the external connections the integrated circuit device may be configured during power-up to a first operating mode, and when the external pull-up resistor may be coupled between the power supply voltage and the one of the external connections the integrated circuit device may be configured during the power-up to a second operating mode.

According to a further embodiment of the method, may comprise the steps of: coupling the internal pull-down resistor to the power supply common during the power-up; and de-coupling the pull-down resistor from the power supply common after the power-up.

According to a yet another embodiment, an integrated circuit device may comprise: a plurality of external connections; a pull-down resistor internal to the integrated circuit device and coupled between a one of the external connections and a power supply common; a plurality of voltage comparators having first inputs coupled to the one of the external connections, and second inputs coupled to a plurality of voltage references having increasing voltages; wherein the integrated circuit device may be configured during power-up to one of a plurality of operating modes depending upon a resistance value of an external pull-up resistor coupled between a power supply voltage and the one of the external connections.

According to a further embodiment, a switch may be coupled between the pull- down resistor and the power supply common, wherein the switch may be closed during the power-up and open after the power-up. According to a further embodiment, the switch may be a field effect transistor. According to a further embodiment, a gray scale to binary encoder may be coupled between outputs of the plurality of voltage comparators and inputs of a plurality of memory devices. According to a further embodiment, one of a plurality of binary values may be stored in the plurality of memory devices depending upon the resistance value of the external pull-up resistor. According to a further embodiment, a zero-binary value may be stored in the plurality of memory devices when the external pull-up resistor may not be coupled to the one of the external connections. According to a further embodiment, the plurality of memory devices may be a plurality of D-flipflops. According to a further embodiment, the plurality of operating modes may select appropriate functions and/or characteristics of the integrated circuit device. According to a further embodiment, the integrated circuit device may be a microcontroller.

According to a further embodiment, a tri-state or open drain driver may be internal to the integrated circuit device and coupled to the one of the external connections. According to a further embodiment, the one of the plurality of binary values may be stored in the plurality of memory devices during assertion of a power-on-reset (POR). According to a further embodiment, the one of the plurality of binary values may be stored in the plurality of memory devices during assertion of a voltage regulator not enabled. According to a further embodiment, the one of the external connections may be at least one of the external connections.

According to still another embodiment, a method for selecting an operating mode for an integrated circuit device may comprise the steps of: providing a plurality of external connections on the integrated circuit device; providing a pull-down resistor internal to the integrated circuit device and coupled between a one of the external connections and a power supply common; providing a plurality of voltage comparators having first inputs coupled to the one of the external connections, and second inputs coupled to a plurality of voltage references having increasing voltages; providing an external pull-up resistor; and configuring the integrated circuit device during power-up to one of a plurality of operating modes depending on a resistance value of the external pull-up resistor coupled between a power supply voltage and the one of the external connections.

According to a further embodiment of the method, may comprise the steps of: coupling the internal pull-down resistor to the power supply common during the power-up; and de-coupling the pull-down resistor from the power supply common after the power-up.

### BRIEF DESCRIPTION OF THE DRAWINGS

A more complete understanding of the present disclosure may be acquired by referring to the following description taken in conjunction with the accompanying drawings wherein:

FIG. 1 illustrates a schematic diagram of a power-up based integrated circuit configuration circuit, according to a specific example embodiment of this disclosure;

FIG. 2 illustrates a schematic diagram of a power-up based integrated circuit configuration circuit, according to another specific example embodiment of this disclosure; and

FIG. 3 illustrates a schematic diagram of a power-up based integrated circuit configuration circuit, according to yet another specific example embodiment of this disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein.

### DETAILED DESCRIPTION

An integrated circuit having a plurality of selectable operating modes, functions and/or characteristics may be configured at the time of product manufacture by providing an appropriate resistance value pull-up resistor at an external connection (pin) of the integrated circuit package. At least one external connection (pin) may be used for such configuration of the integrated circuit. This is done without having to program the integrated circuit before placing on the product printed circuit board. The same integrated circuit may thus be used for a plurality of different products without requiring any pre-programming thereof. The integrated circuit's personality (desired characteristics) will be programmed automatically as soon as power is first applied to the finished product printed circuit board. This will greatly simplify and reduce costs of product manufacturing. Once the integrated circuit has been configured at power up, the external at least one connection (pin), initially used for configuration, can be used for either analog or digital input, output or input/output.

According to various embodiments, an external resistor may be used to pull-up an external connection (pin) of an integrated circuit to a voltage during power-up of the integrated circuit, e.g., microcontroller, microprocessor, analog and digital mixed signal device, programmable logic, memory, display and light emitting diode (LED) and liquid crystal display (LCD) drivers and controllers, wireless devices, etc. An internal to the integrated circuit pull-down resistor forms a series resistor network with this external pull-up resistor. This external pull-up resistor may have a lower value resistance than the internal pull-down resistor such that a sufficient voltage is present at the external connection to be detected as a logic high (“1”). When the external pull-up resistor is connected to the external connection an alternate mode will be detected upon power-up of the integrated circuit. If an external pull-up resistor is not connected to the external connection, then the internal pull-down resistor will pull the external connection to substantially a power supply common or ground voltage and will be detected as a logic low (“0”). This may be considered the “default mode.”

Either operating mode, the default mode or alternate mode, may be stored after power-up of the integrated circuit has occurred. Use of the integrated circuit power-on-reset (POR) or voltage regulator not yet enabled signal may be used for this purpose. A switch (internal transistor) may be used to disconnect the internal pull-down (to ground) resistor after power-up has been completed so that minimum input current will be drawn to the power supply common.

The external pull-up and internal pull-down resistors form a voltage divider circuit. This voltage divider circuit may further be used for selection of one of a plurality of modes by providing a plurality of voltage comparators in the integrated circuit, each voltage comparator set for a different voltage level and the voltage comparison results stored after power-up of the integrated circuit has occurred. By selecting an appropriate value resistance external pull-up resistor connected between the input pad and a power supply voltage, any one of the plurality modes may thereby be selected.

Referring now to the drawings, the details of example embodiments are schematically illustrated. Like elements in the drawings will be represented by like numbers, and similar elements will be represented by like numbers with a different lower case letter suffix.

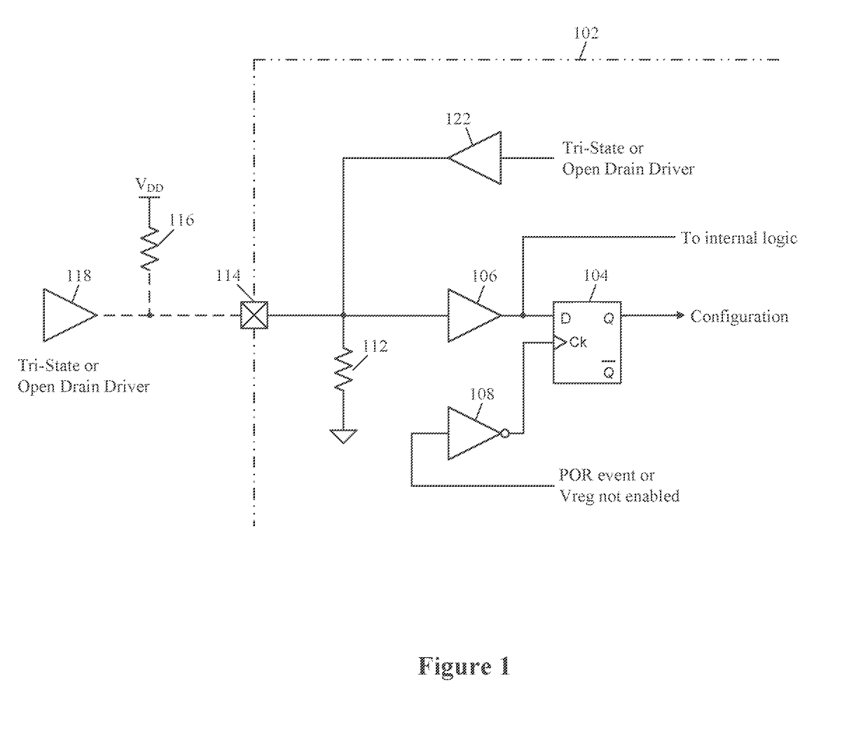

FIG. 1 illustrates a schematic diagram of a power-up based integrated circuit configuration circuit, according to a specific example embodiment of this disclosure. An integrated circuit 102 may comprise a memory storage device 104, e.g., D-flipflop, a buffer 106, an inverter 108, a pull-down resistor 112, an internal driver 122 (optional), and an external connection 114 (pin) on the integrated circuit 102. An external pull-up resistor 116 may be connected to the external connection 114 of the integrated circuit 102 and a power supply voltage, e.g., V_{DD}. An input of the inverter 108 may be coupled to a power-up signal, e.g., power-on-reset (POR), voltage regulator on (Vreg), etc.

The power-up signal will only be present (asserted) when power is first applied to the integrated circuit 102, and may be used for other housekeeping functions such as resetting registers and counters (not shown) that are part of the integrated circuit 102. The power-up signal, for exemplary purposes, may go from a logic 0 to a logic 1 then back to a logic 0, or vice versa. When the power-up signal is asserted to the clock input of the memory storage device 104, the logic value at the input thereof (D) is stored therein and appears as the same logic level on the output (Q). The D-flipflop shown in FIG. 1 may transfer the logic level at its D input to the Q output upon a positive logic voltage edge at the clock input. The inverter 108 will invert the power-up signal so that the D-flipflop will store the logic state from the output of the buffer 106 when the power-up signal goes back to a logic low (“0”). This provides sufficient delay so that the logic level from the output of the buffer 106 has stabilized after power is first applied to the integrated circuit 102.

The buffer 106 may provide a high input impedance so that the pull-down and pull-up resistors 112 and 116, respectively, may be high resistances for reducing circuit and power supply loading. The buffer 106 may further be used as a digital input during normal post-configured operation of the integrated circuit 102. The driver 122 (optional) may be used as a digital output during normal post-configured operation.

If no pull-up resistor 116 is connected to the external connection 114 then the input to the buffer 106 will be at substantially power supply common or ground potential and the output of the buffer will be at logic 0 (low). When the power-up signal (POR) is asserted during powering on the integrated circuit 102, the logic level (low) on the output of the buffer 106 will be stored in the memory storage device 104 and be retained at the output thereof during operation of the integrated circuit 102. When a pull-up resistor 116 is connected to the external connection 114 then the input to the buffer 106 will be at a voltage determined by the series connection of the pull-down resistor 112 and the pull-up resistor 116. If the pull-up resistor 116 has a lower resistance than the pull-down resistor 112 then this voltage will be greater than V_{DD}/2 and output of the buffer 106 may be at a logic high. A logic level high will be stored in the memory storage device 104 and be retained at the output thereof during operation of the integrated circuit 102. Thus, the output logic level of the memory storage device 104 may be used as a configuration bit for selecting and retaining one of two operating modes of the integrated circuit 102.

The resistance values of the pull-down resistor 112 and the pull-up resistor 116 may be large enough to not affect normal operation of the integrated circuit 102, whether the external connection 114 is used as a digital input and/or output. The pull-up resistor 116 may also be used post start-up as a pull-up for an open drain (collector) driver 118.

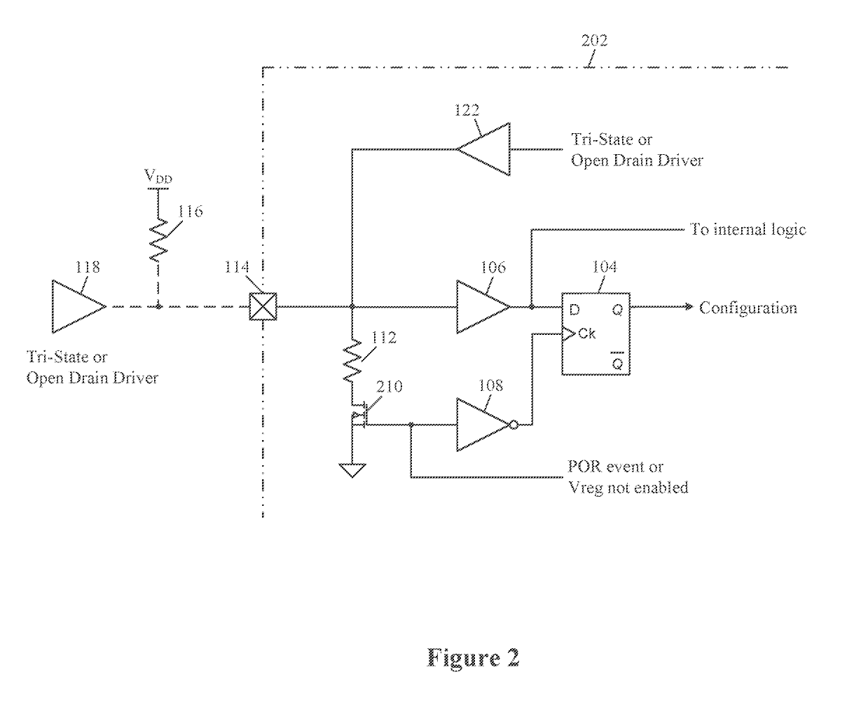

FIG. 2 illustrates a schematic diagram of a power-up based integrated circuit configuration circuit, according to another specific example embodiment of this disclosure. The power-up configuration circuit comprising integrated circuit 202 and shown in FIG. 2 operates in substantially the same way as the circuit described above and shown in FIG. 1 except that a switch 210, e.g., NMOS field effect transistor (FET), NPN bipolar transistor, etc., may be added in series with the pull-down resistor 112. The switch 210 may be controlled by the power-up signal, and when this signal is at a logic high the switch 210 will turn on thereby connecting the pull-down resistor 112 to power supply common or ground. When the power-up signal returns to a logic low during post start-up operation, the switch 210 is off, thereby disconnecting the pull-down resistor 112, whereby the input loading current at the external connection 114 is reduced to a minimum, and the external connection 114 can be used in normal operation as a low input current and high impedance analog or digital input and/or output.

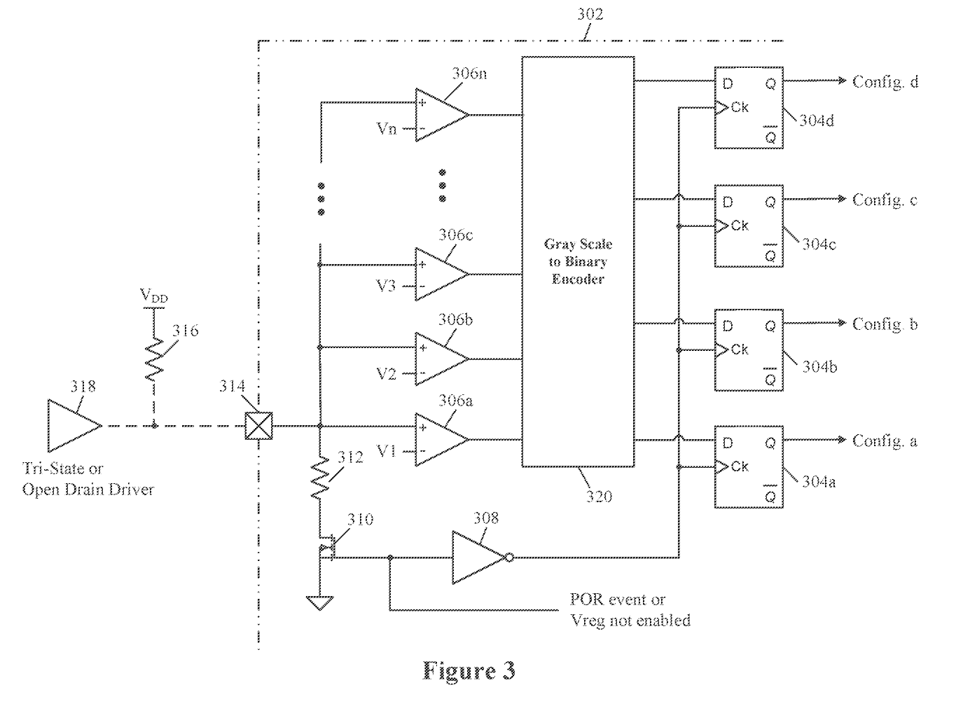

FIG. 3 illustrates a schematic diagram of a power-up based integrated circuit configuration circuit, according to yet another specific example embodiment of this disclosure. An integrated circuit 302 may comprise a plurality of memory storage devices 304, e.g., D-flipflops, a plurality of voltage comparators 306, an inverter 308, a switch 310, a pull-down resistor 312, a grayscale to binary encoder 320, and an external connection 314 on the integrated circuit 302. An external pull-up resistor 316 may be connected to the external connection 314 of the integrated circuit 302 and a power supply voltage, e.g., V_{DD}. An input of the inverter 308 may be coupled to a power-up signal, e.g., power-on-reset (POR), voltage regulator on (Vreg), etc. The power-up signal will only be present when power is first applied to the integrated circuit 102, and may be used for other housekeeping functions such as resetting registers and counters (not shown) that are part of the integrated circuit 102. The power-up signal may, for exemplary purposes, go from a logic 0 to a logic 1 then back to a logic 0, or vice versa.

When the power-up signal is de-asserted the inverter 308 inverts this signal to the clock input of the plurality of memory storage devices 304, and thereby the logic values at the D-inputs thereof are stored therein and appear as the same logic levels on the Q-outputs thereof. The plurality of voltage comparators 306 may provide a high input impedance so that the pull-down and pull-up resistors 312 and 316, respectively, may be high resistances for reducing circuit and power supply loading. When the power-up signal returns to a logic low during post start-up operation, the switch 310 is off, thereby disconnecting the pull-down resistor 312, whereby the input loading current at the external connection 314 is reduced to a minimum, and the external connection 314 can be used in normal operation as a low input current and high impedance analog or digital input and/or output. Not shown is a digital input receiver and/or a digital output driver used during normal post-configured operation of the integrated circuit 302, but are contemplated herein as more fully described above and shown in FIGS. 1 and 2.

If no pull-up resistor 316 is connected to the external connection 314 then the input to the plurality of voltage comparators 306 will be at substantially power supply common or ground potential and the outputs thereof will be at logic 0 (low). When the power-up signal (POR) is asserted during powering on the integrated circuit 302, the logic level (low) on the outputs of the plurality of voltage comparators 306 will be stored in the plurality of memory storage devices 304 and be retained at the output thereof during operation of the integrated circuit 302. When the pull-up resistor 316 is connected to the external connection 314 then the input to the plurality of voltage comparators 306 will be at a voltage determined by the series connection of the pull-down resistor 312 and the pull-up resistor 316.

The voltage at the external connection 314 will be V_{DD}*resistor 312/(resistor 312+resistor 316). By selecting the appropriate resistance value for resistor 316 a specific voltage may be provided to the inputs of the plurality of voltage comparators 306. Wherein if this voltage is greater than V1 but less than V2 then the output of the voltage comparator 306a will be at a logic high and the outputs of the other voltage comparators 306b-306n will be at a logic low. When the voltage at the external input 314 is greater than V2 but less than V3 then the outputs of the voltage comparators 306a and 306b will at a logic high and the outputs of the other voltage comparators 306c-306n will be at a logic low. This voltage detection by the plurality of voltage comparators 306 produces gray scale or temperature level outputs. A gray scale to binary encoder 320 may receive the outputs from the plurality of voltage comparators 306 and produce a binary equivalent thereof that may be used for selection of a specific configuration of the integrated circuit 302. For the four memory storage devices 304 shown in FIG. 3, up to 16 voltage comparators 306 may be used, e.g., one of 16 different modes may be configured through a single external input 314 by selecting the appropriate resistance value for the pull-up resistor 316.

The switch 310, e.g., NMOS field effect transistor (FET), NPN bipolar transistor, etc., may be in series with the pull-down resistor 312. The switch 310 may be controlled by the power-up signal, and when this signal is at a logic high the switch 310 will turn on thereby connecting the pull-down resistor 312 to power supply common or ground. When the power-up signal returns to a logic low during post start-up operation, the switch 310 is off, thereby disconnecting the pull-down resistor 312, whereby the input loading current at the external input 314 is reduced to a minimum, and the external connection 314 can be used in normal operation as a low input current and high impedance analog or digital input and/or output.

1. An integrated circuit device, comprising:
a plurality of external connections; and
a pull-down resistor internal to the integrated circuit device and coupled between a one of the external connections and a power supply common;
wherein the integrated circuit device is configured during power-up to a first or a second operating mode depending upon whether an external pull-up resistor is or is not coupled between a power supply voltage and the one of the external connections.

2. The integrated circuit device according to claim 1, further comprising a switch coupled between the pull-down resistor and the power supply common, wherein the switch is closed during the power-up and open after the power-up.

3. The integrated circuit device according to claim 2, wherein the switch is a field effect transistor.

4. The integrated circuit device according to claim 1, wherein:
a first logic level is detected and stored in the integrated circuit device when the external pull-up resistor is not coupled to the one of the external connections; and
a second logic level is detected and stored in the integrated circuit device when the external pull-up resistor is coupled to the one of the external connections, wherein the stored first or second logic level is used to determine the configuration of the integrated circuit device to the first or second operating mode, respectively.

5. The integrated circuit device according to claim 4, wherein the first or the second logic level is stored in a memory device of the integrated circuit device.

6. The integrated circuit device according to claim 5, wherein the memory device is a D-flipflop whose input is coupled with the one of the external connections through a buffer.

7. The integrated circuit device according to claim 4, wherein the first logic level is a logic 0 and the second logic level is a logic 1.

8. The integrated circuit device according to claim 4, wherein the first operating mode is a default mode and the second operating mode is an alternate mode.

9. The integrated circuit device according to claim 1, wherein the first and second operating modes select appropriate functions and/or characteristics of the integrated circuit device.

10. The integrated circuit device according to claim 1, wherein the integrated circuit device is a microcontroller.

11. The integrated circuit device according to claim 1, further comprising a tri-state or open drain driver internal to the integrated circuit device and coupled to the one of the external connections.

12. The integrated circuit device according to claim 5, wherein the first or second logic level is stored in the memory device of the integrated circuit device during assertion of a power-on-reset (POR).

13. The integrated circuit device according to claim 5, wherein the first or second logic level is stored in the memory device of the integrated circuit device during assertion of a voltage regulator not enabled.

14. The integrated circuit device according to claim 1, further comprising:
a plurality of pull-down resistors internal to the integrated circuit device and coupled between at least some of the external connections and a power supply common;
wherein the integrated circuit device is configured during power-up to at least one first and/or at least one second operating mode depending upon whether an external pull-up resistor is or is not coupled between a power supply voltage and the at least some of the external connections.

15. A method for selecting an operating mode for an integrated circuit device, said method comprising the steps of:
providing a plurality of external connections on the integrated circuit device;
providing a pull-down resistor internal to the integrated circuit device and coupled between a one of the external connections and a power supply common;
providing an external pull-up resistor;
wherein when the external pull-up resistor is not coupled between a power supply voltage and the one of the external connections the integrated circuit device is configured during power-up to a first operating mode, and
when the external pull-up resistor is coupled between the power supply voltage and the one of the external connections the integrated circuit device is configured during the power-up to a second operating mode.

16. The method according to claim 15, further comprising the steps of:
coupling the internal pull-down resistor to the power supply common during the power-up; and
de-coupling the pull-down resistor from the power supply common after the power-up.

17. An integrated circuit device, comprising:
a plurality of external connections;
a pull-down resistor internal to the integrated circuit device and coupled between a one of the external connections and a power supply common;
a plurality of voltage comparators having first inputs coupled to the one of the external connections, and second inputs coupled to a plurality of voltage references having increasing voltages;
wherein the integrated circuit device is configured during power-up to one of a plurality of operating modes depending upon a resistance value of an external pull-up resistor coupled between a power supply voltage and the one of the external connections.

18. The integrated circuit device according to claim 17, further comprising a switch coupled between the pull-down resistor and the power supply common, wherein the switch is closed during the power-up and open after the power-up.

19. The integrated circuit device according to claim 18, wherein the switch is a field effect transistor.

20. The integrated circuit device according to claim 17, further comprising a gray scale to binary encoder coupled between outputs of the plurality of voltage comparators and inputs of a plurality of memory devices.

21. The integrated circuit device according to claim 20, wherein one of a plurality of binary values is stored in the plurality of memory devices depending upon the resistance value of the external pull-up resistor.

22. The integrated circuit device according to claim 20, wherein a zero-binary value is stored in the plurality of memory devices when the external pull-up resistor is not coupled to the one of the external connections.

23. The integrated circuit device according to claim 20, wherein the plurality of memory devices are a plurality of D-flipflops.

24. The integrated circuit device according to claim 17, wherein the plurality of operating modes select appropriate functions and/or characteristics of the integrated circuit device.

25. The integrated circuit device according to claim 17, wherein the integrated circuit device is a microcontroller.

26. The integrated circuit device according to claim 17, further comprising a tri-state or open drain driver internal to the integrated circuit device and coupled to the one of the external connections.

27. The integrated circuit device according to claim 20, wherein the one of the plurality of binary values is stored in the plurality of memory devices during assertion of a power-on-reset (POR).

28. The integrated circuit device according to claim 21, wherein the one of the plurality of binary values is stored in the plurality of memory devices during assertion of a voltage regulator not enabled.

29. The integrated circuit device according to claim 17, wherein the one of the external connections is at least one of the external connections.

30. A method for selecting an operating mode for an integrated circuit device, said method comprising the steps of:
providing a plurality of external connections on the integrated circuit device;
providing a pull-down resistor internal to the integrated circuit device and coupled between a one of the external connections and a power supply common;
providing a plurality of voltage comparators having first inputs coupled to the one of the external connections, and second inputs coupled to a plurality of voltage references having increasing voltages;
providing an external pull-up resistor; and
configuring the integrated circuit device during power-up to one of a plurality of operating modes depending on a resistance value of the external pull-up resistor coupled between a power supply voltage and the one of the external connections.

31. The method according to claim 30, further comprising the steps of:
coupling the internal pull-down resistor to the power supply common during the power-up; and
de-coupling the pull-down resistor from the power supply common after the power-up.
